(19) United States
(12) Patent Application Publication
(10) Pub. No.: US 2014/0295623 A1
(43) Pub. Date: Oct. 2, 2014

(54) METHOD OF PACKAGING A CHIP AND A SUBSTRATE

(71) Applicant: KINSUS INTERCONNECT TECHNOLOGY CORP., Taoyuan (TW)

(72) Inventors: Ting-Hao Lin, Taipei (TW); Yu-Te Lu, Taoyuan Hsien (TW); De-Hao Lu, Taoyuan County (TW)

(73) Assignee: KINSUS INTERCONNECT TECHNOLOGY CORP., Taoyuan (TW)

(21) Appl. No.: 13/853,255

(22) Filed: Mar. 29, 2013

(51) Int. Cl. H01L 21/56

(52) U.S. Cl. CPC H01L 21/561
USPC 438/126

(57) ABSTRACT

Disclosed is a method of packaging a chip and a substrate, including the steps of forming a substrate with a thickness ranging from 70 to 150 μm, which comprises a dielectric layer, a circuit metal layer stacked on the dielectric layer and bonding pads higher than the dielectric layer by 10 to 15 μm; forming a stabilizing structure around the substrate to provide a receiving space; disposing the chip on the receiving space and bonding the pins of the chip with the bonding pads; and filling up the receiving space under the chip with a filling material to a total thickness ranging from 300 to 850 μm. Without the plastic molding process, the present invention reduces the cost and the total thickness, and further prevents the substrate from warping by use of the stabilizing fixing structure.

### BACKGROUND OF THE INVENTION

1. Field of the Invention

The present invention generally relates to a method of packaging a chip and a substrate and more specifically to formation of a stabilizing structure on the thin chip substrate in order to contain the chip therein.

2. The Prior Arts

FIG. 1 illustrates a prior art method of packaging a chip and a substrate. As shown in FIG. 1, a traditional package structure 200 for the chip and the substrate includes a thin chip substrate 1, a chip 50, a filling material 60 and a plastic molding material 90. The thin chip substrate 1 includes a first circuit metal layer 16, a second circuit metal layer 18 and a dielectric layer 30.

The first circuit metal layer 16 is inlaid into the dielectric layer 30 to form a co-plane. The second circuit metal layer 18 is formed on the dielectric layer 30 to fill up the holes in the dielectric layer 30 so as to connect with the first circuit metal layer 16. The thin chip substrate 1 further includes a plurality of bonding pads higher than the co-plane connected to the first circuit metal layer 16, and a solder resist 20 covering the other side of the dielectric layer 30 and part of the second circuit metal layer 18.

The chip 50 has pins 52 connected to the bonding pads 24. The filling material 60 is injected into the part under the chip 50, which is connected to the bonding pads 24 via pins 52. Finally, the chip 50 and the thin chip substrate 1 are enclosed by the plastic molding material 90.

However, one of the shortcomings of the package structure in the prior arts is that the thin chip substrate has a thickness ranging 70 to 150 μm, and the thin chip substrate and the chip package are generally accomplished by various companies using different processes. Further, the thin chip substrate is relatively thin and is easily warped or deformed during the process of transportation or injecting the filling material or enclosing by the plastic molding material. Consequently, the circuit design is greatly limited due to the offset loss in term of compensation so that no finer line width can be created.

Additionally, this package structure has a thickness of about 1.2 mm to 2.0 mm, which is obviously not able to meet the modern requirements of the electronic device, such as thinner and lighter. The cost of the package structure is also high because the plastic molding material is expensive such that it is hard to compete in the market. Therefore, it is needed to provide a new method of packaging a chip and a substrate to assist in designing much finer circuit and thinner package so as to overcome the above problems encountered in the prior art technique.

### SUMMARY OF THE INVENTION

The primary objective of the present invention is to provide a method of packaging a chip and a substrate, which includes the steps of forming a thin chip substrate, forming a stabilizing structure, bonding a chip, and injecting a filling material.

In the step of forming the thin chip substrate, a thin chip substrate with a thickness ranging 70 to 150 μm is formed, and the thin chip substrate includes a dielectric layer, a first circuit metal layer, a second circuit metal layer and bonding pads. The first circuit metal layer is inlaid into the dielectric layer such that the first circuit metal layer and the dielectric layer forms a co-plane. The second circuit metal layer is connected to the first circuit metal layer through holes formed in the dielectric layer. The bonding pads are higher than the co-plane by 10 to 15 μm and are connected to the first circuit metal layer.

In the step of forming the stabilizing structure, the stabilizing structure is formed around the thin chip substrate on the co-plane. The stabilizing structure provides a receiving space for disposing the chip and includes an adhesive layer and a stabilizing layer on the adhesive layer. In the step of bonding the chip, the chip is first disposed on the receiving space and the pins of the chip are bonded with the bonding pads. In the step of injecting the filling material, the filling material is injected to fill up the receiving space under the chip to stabilize the pins of the chip and the bonding pads such that a packaged structure with a total thickness ranging 300 to 850 μm is formed.

One aspect of the present invention is that the cost and the total thickness of the packaged structure can be reduced without the traditional plastic molding process. Furthermore, the present invention can prevent the thin chip substrate from warping and distortion by use of the stabilizing fixing structure so as to achieve much finer and densely circuit layout without considering the compensation for warping.

### BRIEF DESCRIPTION OF THE DRAWINGS

The present invention can be understood in more detail by reading the subsequent detailed description in conjunction with the examples and references made to the accompanying drawings, wherein:

FIG. 1 shows a packaging structure of a chip and a substrate produced according to the prior art method;

FIG. 2 shows a flow diagram of a method of packaging a chip and a substrate according to the present invention;

FIGS. 3A to 3K respectively show a cross-sectional view in one embodiment of a packaged structure illustrating the steps of the method according to of the present invention; and

FIGS. 4J to 4K respectively show a cross-sectional view in another embodiment of the packaged structure illustrating the steps of the method according to of the present invention.

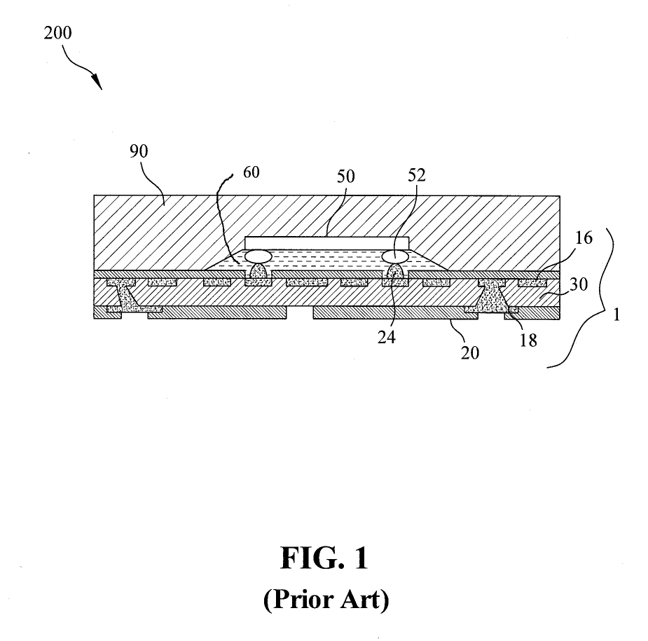

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

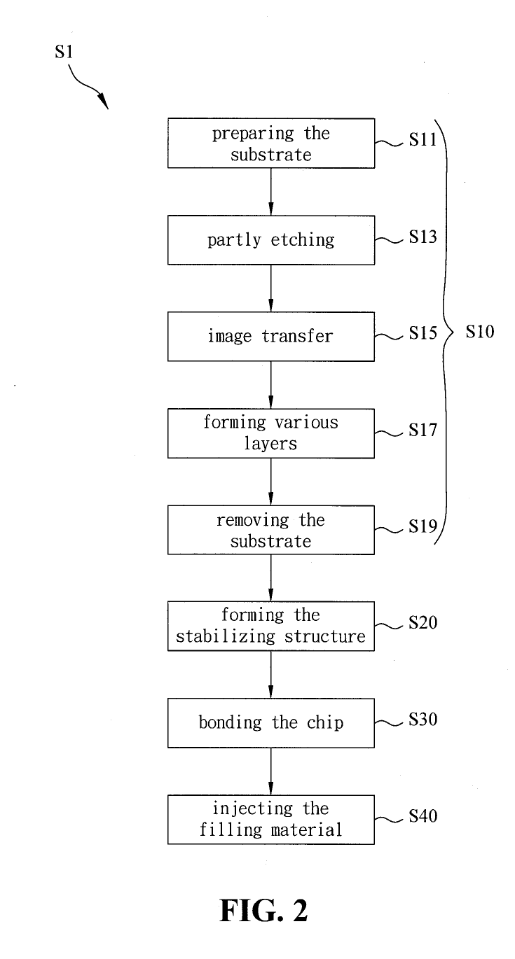

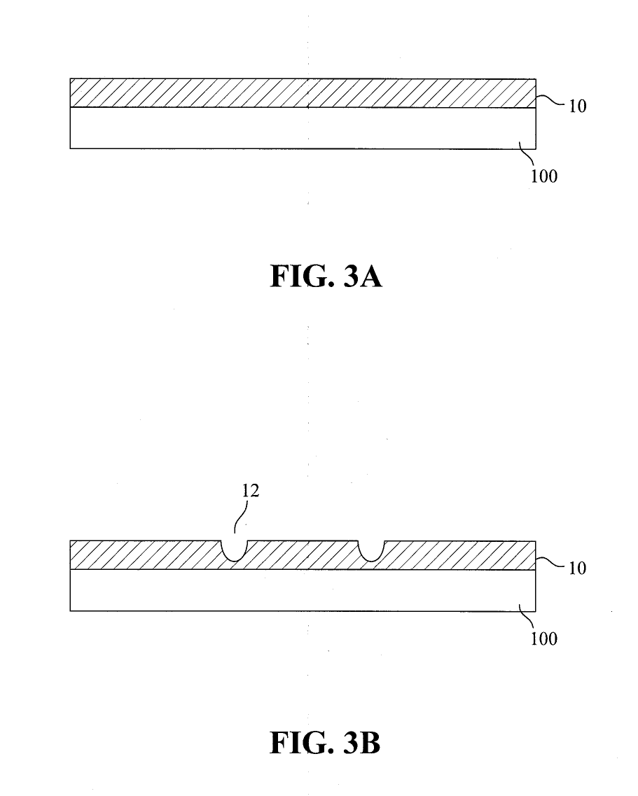

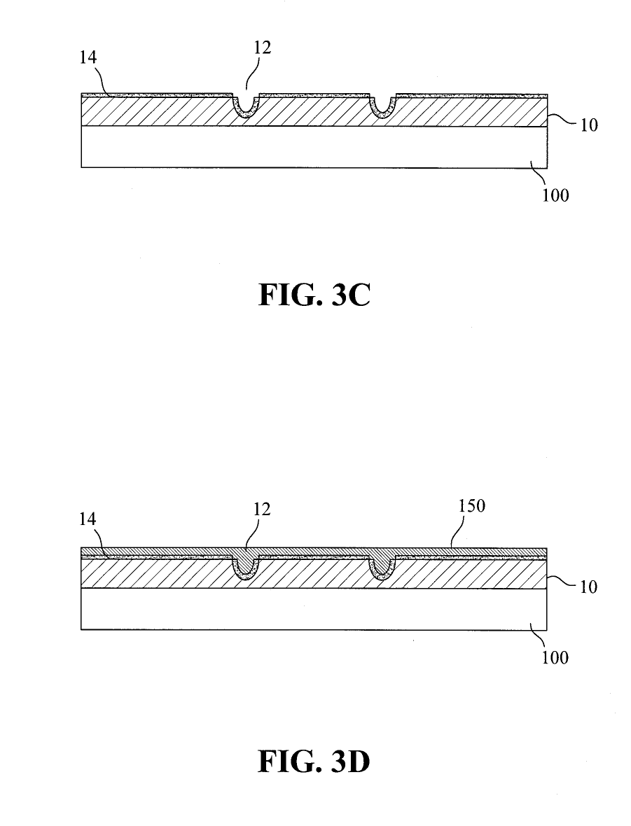

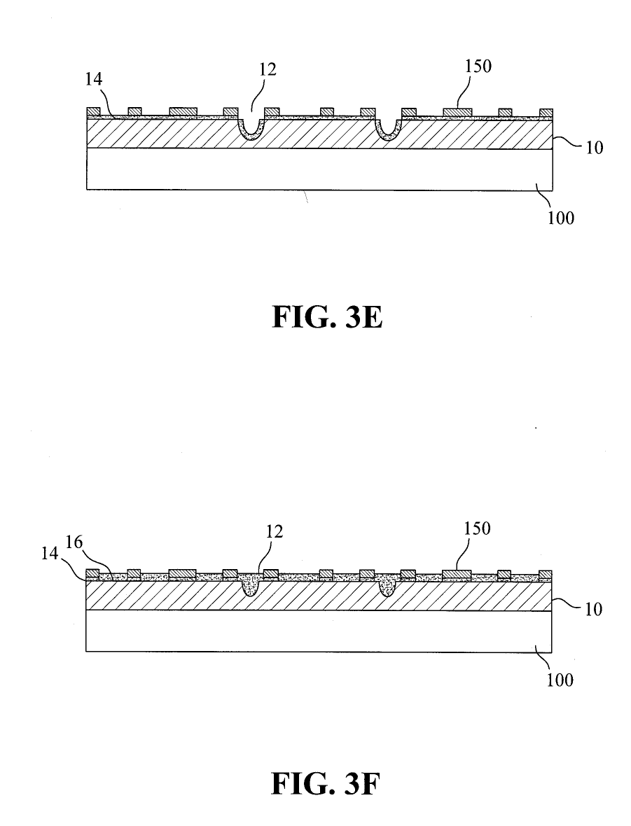

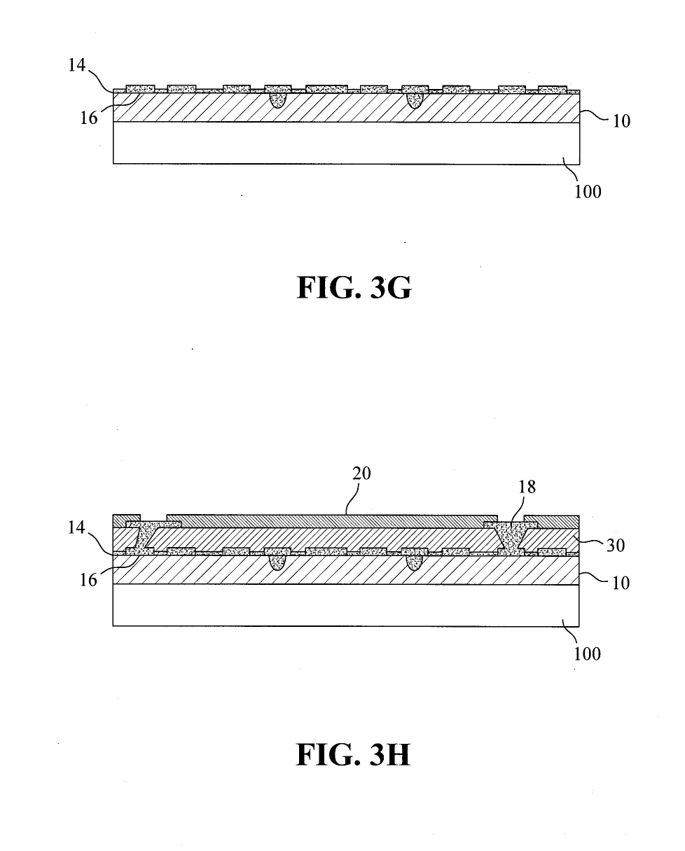

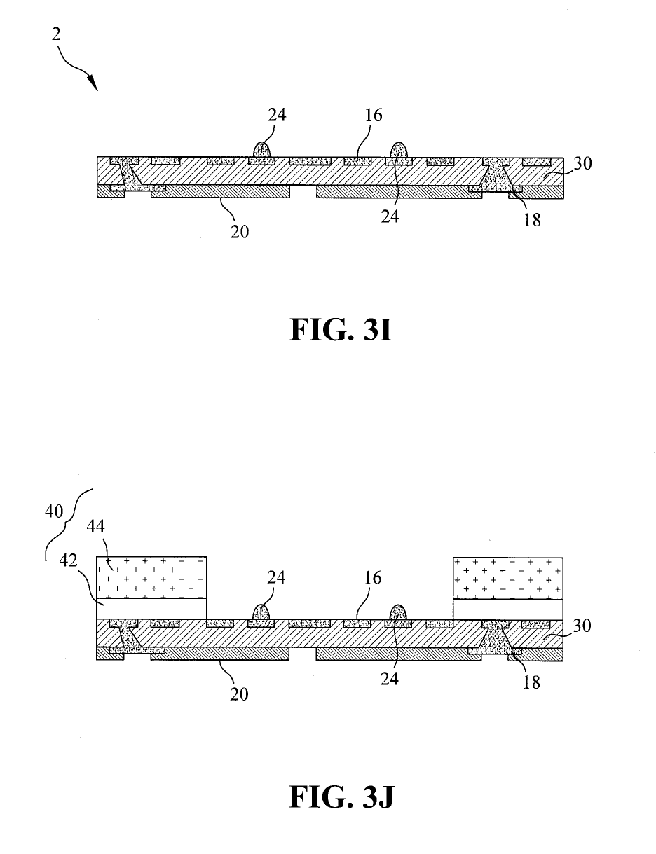

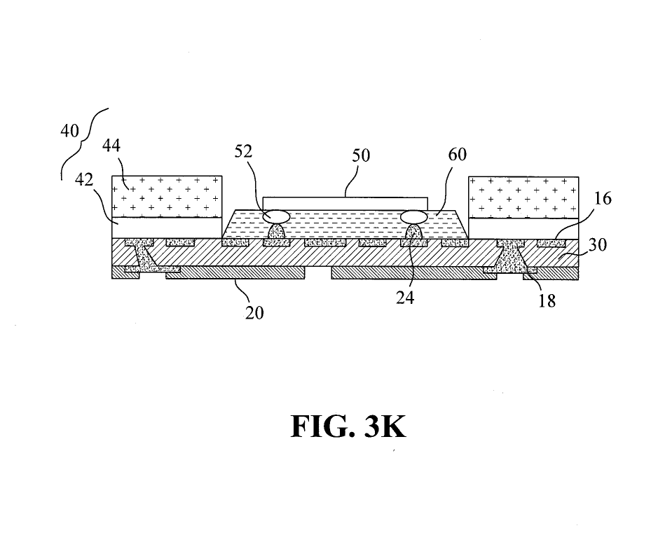

FIG. 2 shows a flow diagram of a method of packaging a chip and a substrate according to the present invention. As shown in FIG. 2, the method of the present invention includes the steps S10, S20, S30 and S40, and the step S10 further includes the steps S11, S13, S15, S17 and S19. Also, to clearly explain the characteristics of the present invention, FIGS. 3A to 3K respectively show a cross-sectional view in one embodiment of a packaged structure illustrating the steps of the method according to of the present invention.

As shown in FIG. 3A, the step 511 is performed to prepare a substrate 100 with a copper layer 10, which has a thickness ranging 25 to 30 μm. Next, in the step S13, the copper layer 10 is processed by dry etching or wet etching to form the holes 12, each having a depth of about 10 to 15 μm, as shown in FIG. 3B.

Then, refer to FIGS. 3C to 3G to illustrate the step S15. First, as shown in FIG. 3C, a conductive metal layer 14 is formed to cover the sidewalls of the holes 12 by the process of electroplating or non-electroplating. Next, the conductive metal layer 14 is covered with a photo resist layer 150, as shown in FIG. 3D. The photo resist layer 150 in FIG. 3E is patterned by the process of exposure and developing. Finally in FIGS. 3F and 3G, the process of electroplating or non-electroplating is performed and the patterned photo resist layer is then removed to form the first circuit metal layer 16, which fills up the holes 12.

As shown in FIG. 3H, the step S17 is performed to form the dielectric layer 30 on the first circuit metal layer 16, and the dielectric layer 30 is drilled to have the holes corresponding to the first circuit metal layer 16. The second circuit metal layer 18 is formed on the dielectric layer 30 by repeating the process similar to the step S15. The second circuit metal layer 18 further fills up the holes in the dielectric layer 30 so as to connect with the first circuit metal layer 16. Finally, the solder resist 20 is formed to cover the dielectric layer 30 and part of the second circuit metal layer 18. As shown in FIG. 31, the substrate 100 is removed in the step S19, and the copper layer 10 and the conductive metal layer 40 are etched off to form the thin chip substrate 2 with a thickness ranging 70 to 150 μm. The first circuit metal layer 16 is formed to inlay into the dielectric layer 30 so as to form the co-plane with the dielectric layer 30. The first circuit metal layer 16 which fills up the holes 12 forms the bonding pads 24 higher than the co-plane by 10 to 15 μm. Therefore, the step S10 is completed.

As shown in FIG. 3J, the step S20 is performed to form a stabilizing structure 40 around the thin chip substrate 2 on the co-plane. The stabilizing structure 40 includes an adhesive layer 42 and a stabilizing layer 44 on the adhesive layer 42. The stabilizing layer 44 is formed from glass fiber, plastic or stainless steel such that the thin chip substrate 2 is stabilized by the stabilizing structure 40 to avoid warping and a receiving space is thus provided.

As shown in FIG. 3K, the step S30 is performed to dispose the chip 50 in the receiving space and solder the pins 52 of the chip 50 with the bonding pads 24, and in the step S40, the filling material is injected into the receiving space under the chip 50 to further fasten the pins 52 of the chip 50 relative to the bonding pads 24. Thus, the substrate and the chip are packaged by the method of the present invention without the traditional plastic molding process, and a resulting thickness ranging 300 to 850 μm is obtained.

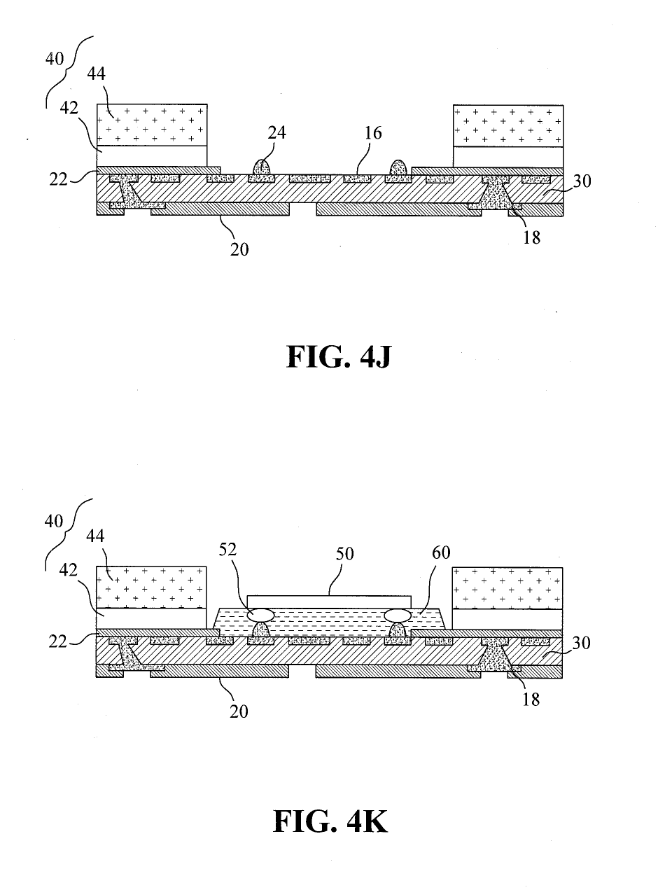

Furthermore, as shown in FIGS. 4J and 4K, before the stabilizing structure 40 is formed, the method of the present invention further includes the steps of forming a second solder resist layer 22 on the co-plane formed by the first circuit metal layer 16 and the dielectric layer 30, and similar to the above-mentioned in FIG. 3K, the stabilizing structure 40 is then formed on the second solder resist layer 22 and the filling material is injected into the receiving space under the chip 50. The second solder resist layer 22 covers part of the co-plane but the bonding pads 24 are not covered by the second solder resist layer 22.

One aspect of the present invention is that the resulting thickness after the packaging process is greatly reduced and the cost is much lower without the traditional plastic molding process. Additionally, the thin chip substrate can get rid of warping and distortion due to the stabilizing structure such that it is possible to implement much finer and densely located circuit without considering the compensation for warping and distortion.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

1. A method of packaging a chip and a substrate, comprising steps of:
forming a thin chip substrate with a thickness ranging from 70 to 150 μm, said thin chip substrate including a dielectric layer, a first circuit metal layer, a second circuit metal layer and bonding pads, wherein the first circuit metal layer is inlaid into the dielectric layer such that the first circuit metal layer and the dielectric layer forms a co-plane, the second circuit metal layer is connected to the first circuit metal layer through holes formed in the dielectric layer while the bonding pads are higher than the co-plane by 10 to 15 μm and are connected to the first circuit metal layer;
forming a stabilizing structure around the thin chip substrate on the co-plane to provide a receiving space for disposing the chip, wherein the stabilizing structure includes a stabilizing layer formed on an adhesive layer with the adhesive layer disposed between the stabilizing layer and the co-plane;
disposing the chip in the receiving space of the thin chip substrate and soldering pins of the chip with the bonding pads; and
injecting a filling material to fill up the receiving space under the chip to stabilize the pins of the chip and the bonding pads such that a packaged structure with a total thickness ranging from 300 to 850 μm is formed;
wherein the stabilizing layer is formed with a top higher than the top of the chip so as to prevent the chip from warping and distortion.

2. The method as claimed in claim 1, wherein the step of forming the substrate further includes the steps of:
preparing the substrate having a copper layer with a thickness ranging from 25 to 30 μm;
forming a plurality of holes in the copper layer by a process of dry etching or wet etching, each hole having a depth ranging from 10 to 15 μm;
performing an image transfer process, which includes the steps of first forming a conductive metal layer by a process of electroplating or non-electroplating to cover sidewalls of the holes, forming a photo resist layer on the conductive metal layer, patterning the photo resist layer by exposure and developing, electroplating or non-electroplating, and finally removing the patterned photo resist layer to form the first circuit metal layer, which fills up the holes;
forming the dielectric layer on the first circuit metal layer, forming the holes in the dielectric layer with respect to the first circuit metal layer by drilling, forming the second circuit metal layer on the dielectric layer to fill up the holes in the dielectric layer so as to connect with the first circuit metal layer, and finally forming a solder resist to cover the dielectric layer and part of the second circuit metal layer; and
removing the substrate and etching off the copper layer and the conductive metal layer to form the thin chip substrate such that the first circuit metal layer is inlaid into the dielectric layer and fills up the holes to form the bonding pads, which are higher than the co-plane by 10 to 15 μm.

3. The method as claimed in claim 1, wherein the stabilizing layer is formed from glass fiber, plastic or stainless steel.

4. (canceled)

5. A method of packaging a chip and a substrate, comprising steps of:
forming a thin chip substrate with a thickness ranging from 70 to 150 μm, said thin chip substrate including a dielectric layer, a first circuit metal layer, a second circuit metal layer and bonding pads, wherein the first circuit metal layer is inlaid into the dielectric layer such that the first circuit metal layer and the dielectric layer forms a co-plane, the second circuit metal layer is connected to the first circuit metal layer through holes formed in the dielectric layer while the bonding pads are higher than the co-plane by 10 to 15 μm and are connected to the first circuit metal layer;
forming a solder resist layer on the co-plane of the thin chip substrate to cover part of the co-plane but not the bonding pads;
forming a stabilizing structure on the solder resist layer around the thin chip substrate to provide a receiving space for disposing the chip, wherein the stabilizing structure includes a stabilizing layer formed on an adhesive layer with the adhesive layer disposed between the stabilizing layer and the solder resist layer;
disposing the chip in the receiving space of the thin chip substrate and soldering pins of the chip with the bonding pads; and
injecting a filling material to fill up the receiving space under the chip to stabilize the pins of the chip and the bonding pads such that a packaged structure with a total thickness ranging from 300 to 850 μm is formed;
wherein the stabilizing layer is formed with a top higher than the top of the chip so as to prevent the chip from warping and distortion.

6. The method as claimed in claim 5, wherein the step of forming the substrate further includes the steps of:
preparing the substrate having a copper layer with a thickness ranging from 25 to 30 μm;
forming a plurality of holes in the copper layer by a process of dry etching or wet etching, each hole having a depth ranging from 10 to 15 μm;
performing an image transfer process, which includes the steps of first forming a conductive metal layer by a process of electroplating or non-electroplating to cover sidewalls of the holes, forming a photo resist layer on the conductive metal layer, patterning the photo resist layer by exposure and developing, electroplating or non-electroplating, and finally removing the patterned photo resist layer to form the first circuit metal layer, which fills up the holes;
forming the dielectric layer on the first circuit metal layer, forming the holes in the dielectric layer with respect to the first circuit metal layer by drilling, forming the second circuit metal layer on the dielectric layer to fill up the holes in the dielectric layer so as to connect with the first circuit metal layer, and finally forming a solder resist to cover the dielectric layer and part of the second circuit metal layer; and
removing the substrate and etching off the copper layer and the conductive metal layer to form the thin chip substrate such that the first circuit metal layer is inlaid into the dielectric layer and fills up the holes to form the bonding pads, which are higher than the co-plane by 10 to 15 μm.

7. The method as claimed in claim 5, wherein the stabilizing layer is formed from glass fiber, plastic or stainless steel.
